(19) United States
(12) Patent Application Publication
(10) Pub. No.: US 2007/0047203 A1
(43) Pub. Date: Mar. 1, 2007

(54) Integral liquid cooling computer housing

(76) Inventor: Wen-Han Chen, Sanchong City (TW)

Correspondence Address: TROXELL LAW OFFICE PLLC, SUITE 1404, 5205 LEESBURG PIKE, FALLS CHURCH, VA, 22041, US

(21) Appl. No.: 11/215,025

(22) Filed: Aug. 31, 2005

(51) Int. Cl. H05K 7/20

(52) U.S. Cl. 361/698

(57) ABSTRACT

The invention provides an integral liquid cooling computer housing including a computer housing, which is provided with an accommodating platform and a movable cover at one side thereof. Component devices of a liquid cooling system are installed to the accommodating platform without needing additional space outside the computer housing for fully utilizing available space as well as giving an appealing appearance. The movable cover is for covering the accommodating platform for concealing or exposing the accommodating platform, and for shielding against noises, thereby facilitating installation thereof and minimizing usage noises. The movable cover is configured with a plurality of ventilation holes for a liquid cooling system installed to the accommodating platform to discharge hot air out of the computer housing, thereby obtaining optimal heat dissipating effects.

### BACKGROUND OF THE INVENTION

(a) Field of the Invention

The invention relates to an integral liquid cooling computer housing, and more particularly, to a liquid cooling computer housing that is devised with a variation at internal space thereof and an accommodating platform at one side therein.

(b) Description of the Prior Art

Referring to FIG. 1 and FIG. 2, a body A is a prior computer housing. Supposed a liquid cooling system B having a liquid tank B2, a dissipating device B3, a fan apparatus B4, a motor apparatus B5 and a heat conducting plate B6 is to be installed to a computer housing, it is necessary that surroundings of the computer housing be reserved with spaces for placing the liquid cooling system B. However, spaces are undesirably occupied in addition to unpleasant noises resulted.

Component devices of the liquid cooling system B is connected using pipes B1. The heat conducting plate B6 is connected from an exterior to a central processing unit (CPU) at an interior of the computer housing. Hence, for that the pipes B1 connected with the heat conducting plate B6 are moved along with movements of external component devices, devices at the interior of the computer housing are likely damaged from frequent contacts.

It is a vital task of the invention as how to overcome the aforesaid drawbacks.

### SUMMARY OF THE INVENTION

The invention provides an integral liquid cooling computer housing, which is devised with a, variation at internal space thereof with an accommodating platform at one side therein. The accommodating platform serves as an exclusive space for placing a liquid cooling system having a liquid tank, a dissipating device, a fan apparatus and a motor apparatus, thereby forming an integral structure by installing the liquid cooling system in the computer housing. Furthermore, a movable cover is devised for covering the accommodating platform to conceal or expose the accommodating platform, and is configured with a plurality of ventilation openings for discharging hot air from an interior of the computer housing to surroundings thereof.

To better understand characteristics, functions and effects of the invention, detailed descriptions of a preferred embodiment shall be given with the accompanying drawings below.

### BRIEF DESCRIPTION OF THE DRAWINGS

FIG. 1 shows an elevational view of a prior art.

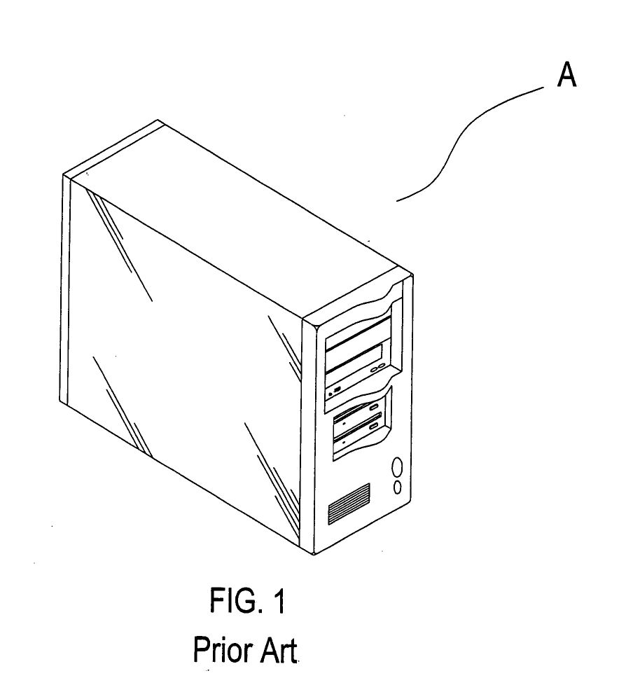

FIG. 2 shows a view of an embodiment according to the prior art.

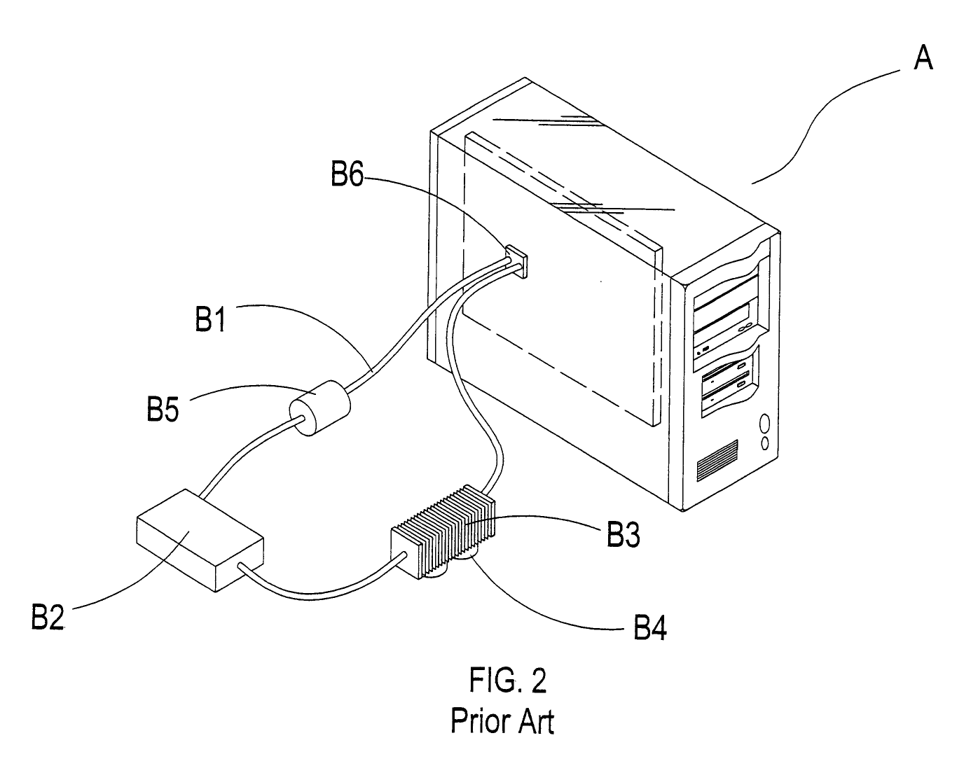

FIG. 3 shows an elevational according to the invention.

FIG. 4 shows an exploded elevational view according to the invention.

FIG. 5 shows a view of an embodiment according to the invention.

FIG. 6 shows a view of another embodiment according to the invention.

### DETAILED DESCRIPTION OF THE PREFERRED EMBODIMENTS

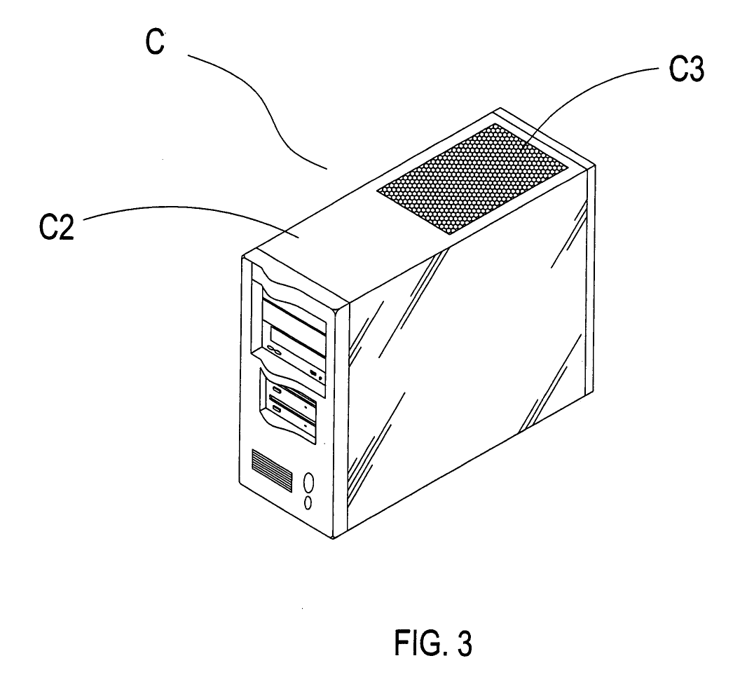

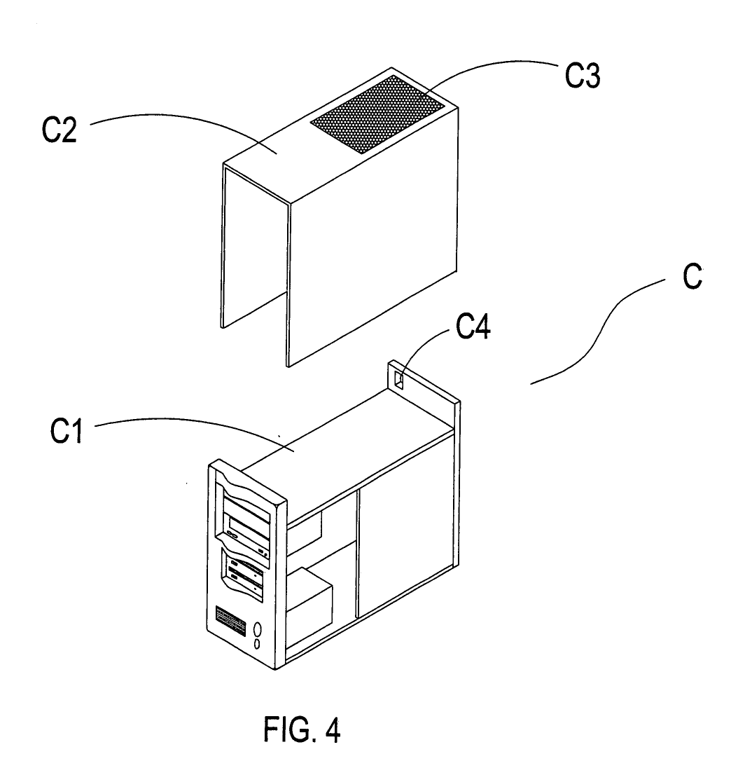

With reference to FIG. 3 and FIG. 4, an integral liquid cooling housing according to the invention comprises a computer housing C having an accommodating platform C1 and a movable cover C2. The accommodating platform C1 is provided with a space for accommodating a liquid cooling system having a liquid tank, a dissipating device, a fan apparatus, and a motor apparatus. The accommodating platform C1 is devised at an interior of the computer housing C. Therefore, when the liquid cooling system is installed to the accommodating platform C1, a distance between the liquid cooling system and component devices in the computer housing is shortened, so as to reduce a length of connecting pipes to further prevent liquid leakage due to excessive lengths, while also fully utilizing available space and maintaining an appealing appearance. The accommodating platform C1 is provided with a liquid exchange opening C4 for supplying and discharging liquid at an edge thereof, thereby allowing liquid exchange of a liquid in the liquid cooling system without having to disassembling the computer housing C.

The movable cover C2 is for covering the accommodating platform C1 and concealing the accommodating platform C1 within the computer housing C to shield against noises and to maintain an appealing appearance. Or, the movable cover C2 is lifted to expose the accommodating platform C1 to facilitate installation and cleaning dirt accumulated at the dissipating device of the liquid cooling system due to the fan apparatus. The movable cover C2 is configured with a plurality of ventilation holes C3 for the fan apparatus of the liquid cooling system installed to the accommodating platform to rapidly discharge hot air from an interior of the computer housing C to surroundings of the computer housing, thereby obtaining optimal heat dissipating effects.

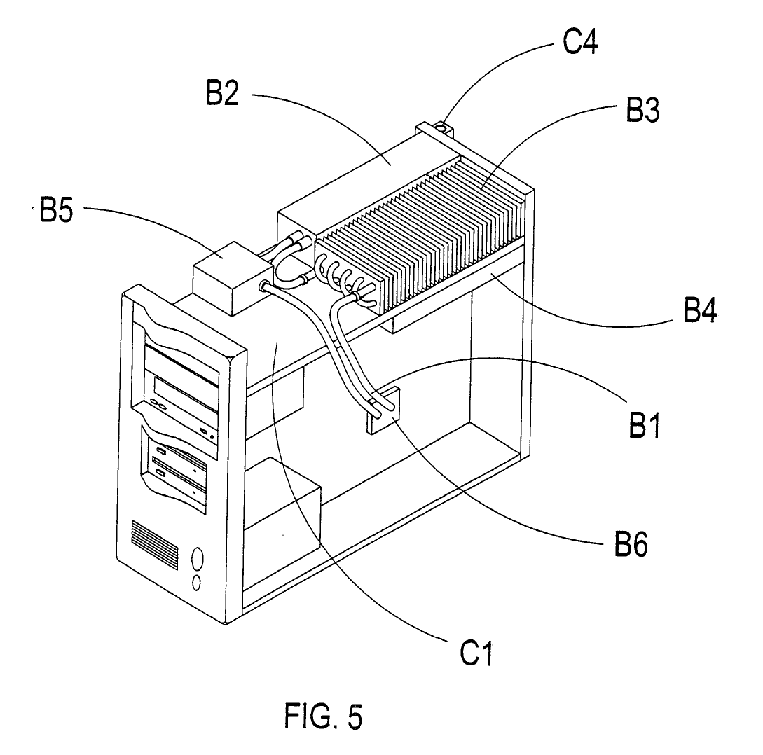

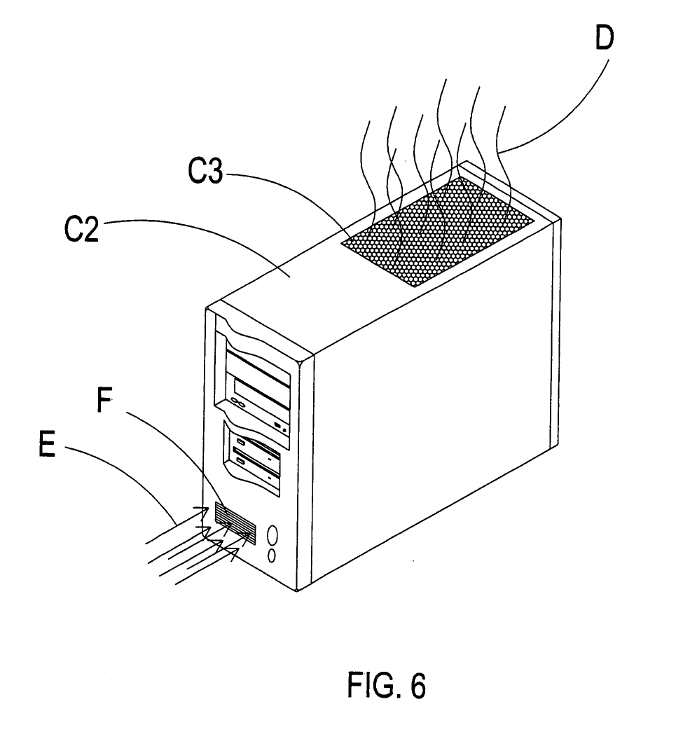

Referring to FIG. 5 and FIG. 6 showing an embodiment according to the invention, the computer housing C is provided with an accommodating platform C1 and a movable cover C2 at a side thereof. The accommodating platform C1 is provided with a space for accommodating a liquid cooling system having a liquid tank B2, a dissipating device B3, a fan apparatus B4, and a motor apparatus B5. The accommodating platform C1 is devised at an interior of the computer housing C to fully utilize available space. The movable cover C2 is for covering the accommodating platform C1 in order to conceal or expose the accommodating platform C1 in the computer housing C1. The movable cover C2 is configured with a plurality of ventilation holes C3 for the liquid cooling system installed to the accommodating platform C1 to rapidly discharge hot air from an interior of the computer housing C to surroundings of the computer housing, thereby obtaining optimal heat dissipating effects.

Component devices of the liquid cooling system are connected using pipes B1. Using operations of the motor apparatus B5 of the liquid cooling system, a liquid in the water tank B2 is circulated via the connected pipes B1. The heat conducting plate B6 of the liquid cooling system is connected with a central processing unit (CPU) in the computer housing C. Heat produced from the operating CPU is taken away by the liquid circulating in the heat conducting plate B6, thereby obtaining heat dissipating effects by rapidly lowering the temperature. Temperature of the heated liquid is absorbed and dispersed by the dissipating device B3, and heated air distributed at the dissipating device B3 from the fan apparatus B4 is discharged out of the computer housing C through the plurality of ventilation holes C3 at the movable cover C2. Owing to the principle of hot air D rising from thermal convection in the computer housing C, the hot air D is successfully discharged through the ventilation holes C3, while cold air E is entered into the computer housing C through an opening F at a lower section of the computer housing C, thereby enhancing dissipation effects in the computer housing C. In addition, noise reduction of the computer housing C is optimized because the movable cover C2 is capable of shielding against noises.

To distinguish novelty and practicability of the invention, the present invention is compared With the prior art as below.

Shortcomings of the prior art are:
1. Space is wasted for that component devices of a liquid cooling system are placed at surroundings of a computer housing.
2. Installation process of a liquid cooling system is complicated due to required alteration of the computer housing.
3. External pipes need to be connected to a liquid cooling system. When component devices of the liquid cooling system are moved, devices in a computer housing are likely damaged along with movements and contacts of the pipes.
4. After disassembling a computer housing and installing a liquid cooling system, the computer housing cannot be restored to an original installation thereof due to external pipes connected to result in a messy and unattractive appearance.
5. Liquid leakage can be incurred from damages caused by excessively lengthy pipes connecting a liquid cooling system.

Excellences of the invention are:
1. Available space is fully utilized by installing the liquid cooling system to the accommodating platform in the computer housing.
2. Damages of devices in the computer housing caused by contact are prevented for that the installed liquid cooling system does not require externally connected pipes.
3. The computer housing is given an appealing appearance since the liquid cooling system is installed in the computer housing while also concealed by the movable cover.
4. Installation process of the liquid cooling system to the accommodating platform is made easy with a simple step of opening the movable cover without any alterations of the computer housing.
5. Lengths of connecting pipes needed for installing the liquid cooling system into the computer housing are reduced to prevent potential damages and leakage resulted from excessive lengths of the pipes.
6. Based on the principle of thermal convection of hot air in the computer housing, the fan apparatus of the liquid cooling system is allowed to rapidly discharge hot air through the ventilation holes at the movable cover, thereby optimizing heat dissipating effects.
7. The invention provides novelty and practicability.
8. The invention elevates industrial competitiveness.

It is of course to be understood that the embodiment described herein is merely illustrative of the principles of the invention and that a wide variety of modifications thereto may be effected by persons skilled in the art without departing from the spirit and scope of the invention as set forth in the following claims.

What is claimed is:

1. An integral liquid cooling computer housing comprising a computer housing, which has an accommodating platform and a movable cover at an upper side of an interior thereof; wherein:
the accommodating platform serves as an exclusive space for placing a liquid cooling system, and is devised at an interior of the computer housing, thereby fully utilizing available space when installing the liquid cooling system in the computer housing while providing an integral structure;
the movable cover is for covering the accommodating platform and is even with outer edges of the computer housing for concealing or exposing the accommodating platform in the computer housing; the movable cover also has a plurality of ventilation holes for discharging hot air in the computer housing; and the accommodating platform has an edge thereof provided with a liquid exchange opening for supplying and a discharging liquid, thereby allowing liquid exchange of a liquid in the liquid cooling system without having to disassembling the computer housing; and
the liquid cooling system has a liquid tank, a dissipating device, a fan apparatus and a motor apparatus installed to the accommodating platform in the computer housing to shorten a distance between the liquid cooling system and component devices in the computer housing, thereby reducing lengths of connecting pipes and further preventing damages and leakage caused by excessive lengths of the pipes.

2. The integral liquid cooling computer housing in accordance with claim 1, wherein the accommodating platform is devised at internal sections joining with an outer edge of the computer housing including a front side, rear side, lower side and lateral side of the computer housing.

3. The integral liquid cooling computer housing in accordance with claim 1, wherein the accommodating platform is for placing an air cooling system, a heat conducting pipe cooling system, a micro air conditioning system (MASC) and other related cooling systems.
